(19) United States
(12) Patent Application Publication
(10) Pub. No.: US 2009/0011220 A1
(43) Pub. Date: Jan. 8, 2009

(54) Carrier and method for manufacturing printed circuit board

(75) Inventors: Jung-Hyun Park, Daejeon (KR); Jeong-Woo Park, Suwon-si (KR); Sang-Duck Kim, Suwon-si (KR); Jong-Gyu Choi, Suwon-si (KR); Ji-Eun Kim, Gwangmyeong-si (KR); Myung-Sam Kang, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/153,155

(22) Filed: May 14, 2008

(30) Foreign Application Priority Data
Jul. 4, 2007 (KR) 10-2007-0066894

(51) Int. Cl. H05K 1/05; B29C 65/42; B32B 7/00; B32B 7/12

(52) U.S. Cl. 428/317.5; 156/152; 428/411.1; 428/457; 428/413; 428/473.5; 428/426; 428/537.5; 428/421

(57) ABSTRACT

A carrier and a method for manufacturing a printed circuit board are disclosed. The method for manufacturing a printed circuit board may include: forming a first circuit pattern on each of a pair of release layers, which are attached respectively to either side of a base layer by adhesive layers; detaching the pair of release layers from the base layer; stacking and pressing the pair of release layers onto either side of an insulation substrate such that the first circuit patterns are buried in the insulation substrate; and separating the pair of release layers. By forming a circuit pattern on each of a pair of release layers with a single process, and transferring the circuit pattern into each side of an insulation substrate, the manufacturing process can be shortened and circuit patterns can be formed to a high density.

### CROSS-REFERENCE TO RELATED APPLICATIONS

This application claims the benefit of Korean Patent Application No. 10-2007-0066894 filed with the Korean Intellectual Property Office on Jul. 4, 2007, the disclosure of which is incorporated herein by reference in its entirety.

### BACKGROUND

1. Technical Field

The present invention relates to a carrier and a method for manufacturing a printed circuit board.

2. Description of the Related Art Developments in the electronics industry have promoted smaller and more functionalized electronic parts, such as in mobile phones, etc., and as a result, there is a growing demand for smaller and higher-density printed circuit boards. According to such trends towards lighter, thinner, and simpler electronic products, so also is the printed circuit board being endowed with finer patterns, smaller sizes, and packaged forms.

A technique currently in wide use for manufacturing fine circuit patterns is photolithography, which is a method of forming patterns on a board coated with a thin film of photoresist. When employing this method, however, as the degree of integration is increased for semiconductor components, an exposure technique for shorter frequencies may be required, in order to form fine-lined patterns.

Processes such as MSAP (modified semi-additive process), SAP (semi-additive process), etc., have also been used as methods of implementing high densities for fine-line circuit patterns, in which circuits are selectively grown on a thin copper film. However, there may be difficulties in applying these methods, due to the additional infrastructure required in terms of materials and investments for new equipment, and because damage may occur on the finished circuits during the procedures for removing portions of the thin copper film that are not used as circuits, so that the target circuit width may not be obtained. Furthermore, the circuit patterns formed according to such methods are exposed at the upper portion of the insulation substrate, so that the overall height of the board is great, and undercuts can occur at the attachment portions between the circuit patterns and the insulation substrate, causing the circuits to be detached from the insulation substrate.

### SUMMARY

An aspect of the invention is to provide a carrier and a method of manufacturing a printed circuit board, in which circuit patterns can be transcribed onto an insulation substrate using the carrier, to shorten the manufacturing process, and form high-density circuit patterns.

Another aspect of the invention provides a carrier that includes a base layer; a pair of adhesive layers, each of which is stacked on either side of the base layer, and which are of such quality that the adhesive strengths of the adhesive layers are lowered with an application of a predetermined stimulant; and a pair of release layers, which are attached respectively to the pair of adhesive layers.

The release layers may include at least one of a conductive metal and an insulating material.

The conductive metal may contain at least one selected from a group consisting of copper (Cu), gold (Au), silver (Ag), nickel (Ni), palladium (Pd), and platinum (Pt).

The insulating material may be made of at least one or more selected from a group consisting of epoxy resin, polyimide, phenol, fluorine resin, PPO (polyphenylene oxide) resin, BT (bismaleimide triazine) resin, glass fiber, and paper.

The predetermined stimulant may be ultraviolet rays or heat.

The adhesive layers may be made of expandable adhesive.

Yet another aspect of the invention provides a method for manufacturing a printed circuit board, where the method includes: forming a first circuit pattern on each of a pair of release layers, which are attached respectively to either side of a base layer by adhesive layers; detaching the pair of release layers from the base layer; stacking and pressing the pair of release layers onto either side of an insulation substrate such that the first circuit patterns are buried in the insulation substrate; and separating the pair of release layers.

The method may further include, after separating the pair of release layers, stacking a build-up layer over the insulation substrate and forming a via, which is electrically connected with the first circuit pattern, and a second circuit pattern.

Multiple build-up layers may be stacked, where the via and the second circuit pattern may stacked on each build-up layer.

The release layers may be made of a conductive metal. In this case, the operation of forming the first circuit pattern can include: forming a plating resist, which is in correspondence with the first circuit pattern, over the release layer; performing electroplating with the conductive metal as an electrode; and removing the plating resist. Also, the operation of separating the pair of release layers can include etching the conductive metal.

The release layers may be made of an insulating material. In this case, the operation of forming the first circuit pattern can include: forming a metal layer over the release layer, forming a plating resist in correspondence with the first circuit pattern, performing electroplating with the metal layer as an electrode, and removing the plating resist.

The release layers may consist of an insulation layer and a metal layer stacked on the insulation layer. In this case, the operation of forming the first circuit pattern may include: forming an etching resist, which is in correspondence with the first circuit pattern, over the pair of the release layers; etching the metal layer; and removing the etching resist.

The adhesive layers may be such that the adhesive strengths of the adhesive layers are lowered with an application of a predetermined stimulant, and the operation of detaching the pair of release layers may include applying the predetermined stimulant to the adhesive layer. In this case, the predetermined stimulant may be ultraviolet rays or heat.

The adhesive layers may be made of expandable adhesive.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a carrier according to an embodiment of the invention.

FIG. 2 is a flowchart for a method of manufacturing a printed circuit board according to an embodiment of the invention.

FIG. 3, FIG. 4, FIG. 5, FIG. 6, FIG. 7, FIG. 8, FIG. 9, and FIG. 10 are cross-sectional views representing a flow diagram for a method of manufacturing a printed circuit board according to an embodiment of the invention.

FIG. 11, FIG. 12, and FIG. 13 are cross-sectional views representing a flow diagram for a portion of a method of manufacturing a printed circuit board according to another embodiment of the invention.

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention. The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The carrier and method for manufacturing a printed circuit board according to certain embodiments of the invention will be described below in more detail with reference to the accompanying drawings, in which those components are rendered the same reference number that are the same or are in correspondence, regardless of the figure number, and redundant explanations are omitted.

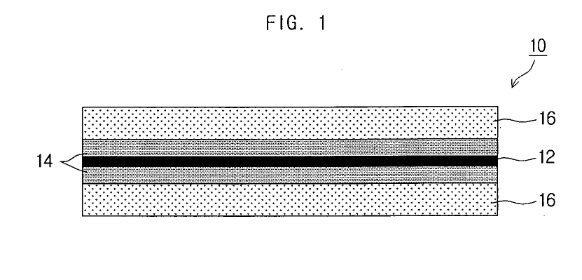

FIG. 1 is a cross-sectional view of a carrier according to an embodiment of the invention. In FIG. 1, there are illustrated a base layer 12, adhesive layers 14, and release layers 16.

A carrier 10 according to this particular embodiment of the invention may include a base layer 12, a pair of adhesive layers, which may be stacked respectively on each side of the base layer 12, and which may be of such quality that the adhesive strengths are lowered with the application of a predetermined stimulant, and a pair of release layers 16, which may be attached respectively onto each of the pair of adhesive layers 14. Circuit patterns may be formed respectively on the pair of release layers 16 of the carrier 10, and the release layers 16 on which the circuit patterns are formed may be detached, to transfer the circuit patterns into an insulation substrate 26. In this way, a printed circuit board can easily be fabricated by forming the circuit patterns on both sides of the carrier at the same time and transferring each of the circuit patterns formed on the carrier into either side of the insulation substrate.

The base layer 12 may divide the adhesive layers 14 formed over the base layer 12 in two, so that the release layers 16 attached to the adhesive layers 14 may be detached separately. Paper, non-woven fabric, and synthetic resins such as polyethylene, polypropylene polyisobutylene, etc., may be used as the base layer 12.

The adhesive layers 14 may be stacked on either side of the base layer 12, and the adhesive layers 14 may be of such quality that the adhesive strengths of the adhesive layers 12 are lowered with the application of a predetermined stimulant. The stimulant may be ultraviolet rays or heat. The release layers 16 attached to the adhesive layers 14 may remain attached on the adhesive layers 14, until the stimulant is applied, at which the release layers 16 may easily be detached from the base layer 12.

As the property of the adhesive which forms the adhesive layers 14 may be changed with the application of the predetermined stimulant for lowering the adhesive strength, the release layers 16 may easily be detached from the base layer 12. For example, the adhesive layers 14 may be formed by an adhesive that contains a material which generates gas when ultraviolet rays are applied. Then, when detaching the release layers 16, ultraviolet rays may be irradiated to generate gas in the adhesive layers, at which the volume of the adhesive layers 14 may be changed, such that the adhesive strengths may be lowered.

In another example, the adhesive layers 14 may be formed using an expandable adhesive containing a material that foams when heat is applied to a predetermined temperature. Then, when detaching the release layers 16, heat may be applied to the adhesive layers 14, until a predetermined temperature is reached at which foam is created in the adhesive layers 14. As the adhesive surface becomes uneven, the adhesive strength may be decreased.

The release layers 16 may remain attached to the base layer 12 by the adhesive layers 14 and then may be detached from the base layer 12 when necessary. For example, relievo circuit patterns may be formed on the release layers 16, and the release layers 16 may be detached from the base layer 12, to be stacked and pressed into the insulation substrate 26 such that the relievo circuit patterns are buried in the deformable insulation substrate 26. Afterwards, the release layers 16 may be separated from the insulation substrate 26, so that an insulation substrate 26 may be formed that has the circuit patterns buried within.

The release layers 16 may be separated from the base layer 12 by lowering the adhesive strengths of the adhesive layers 14, which are interposed between the base layer 12 and the release layers 16. That is, the adhesive strengths of the adhesive layers 14 may be lowered by applying a predetermined stimulant to the adhesive, to separate the release layers 16 from the base layer 12.

The release layers 16 can be made of at least one of a conductive metal or an insulation material. For example, a release layer 16 may be made of an insulation layer made of an insulating material, a metal layer made of a conductive metal, or a metal layer made of conductive metal stacked over an insulation layer made of an insulation material. The conductive metal may contain at least one or more selected from a group consisting of copper (Cu), gold (Au), silver (Ag), nickel (Ni), palladium (Pd), and platinum (Pt). That is, the release layer 16 can be made of one of such metals, or can be made using such metals in combination.

Also, the insulating material can be made of at least one or more selected from a group consisting of epoxy resin, polyimide, phenol, fluorine resin, PPO (polyphenylene oxide) resin, BT (bismaleimide triazine) resin, glass fiber, and paper. For instance, the release layer 16 can be made of the epoxy resin as a base and a reinforcing material such as paper, glass fiber, and glass non-woven fabric, or can be made of polyimide by itself.

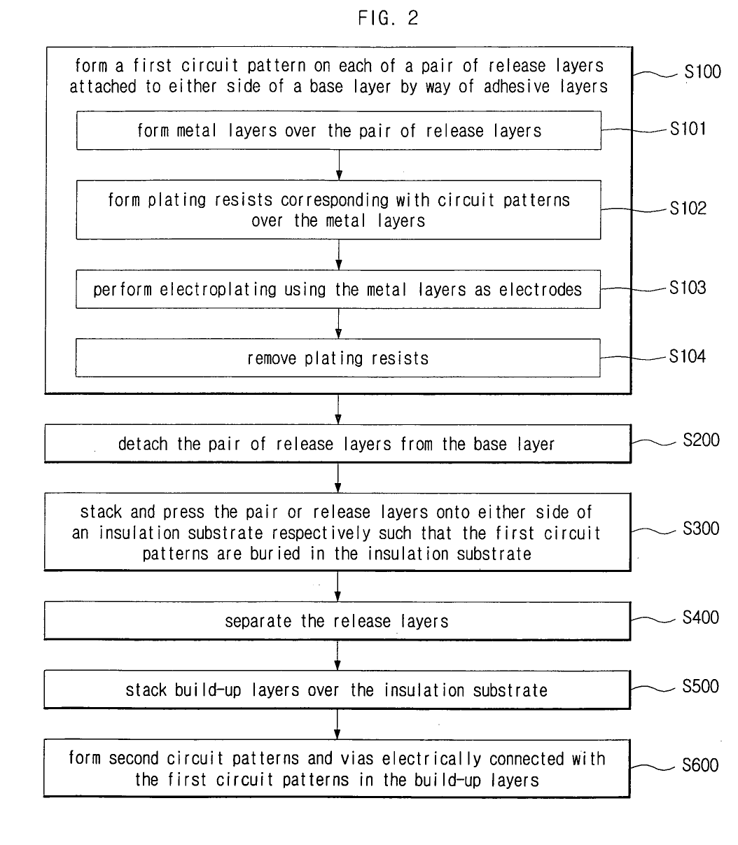

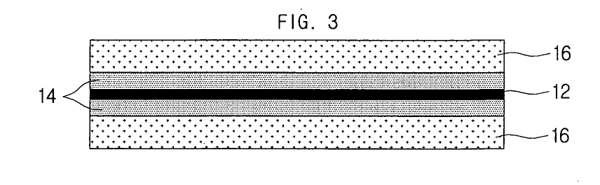

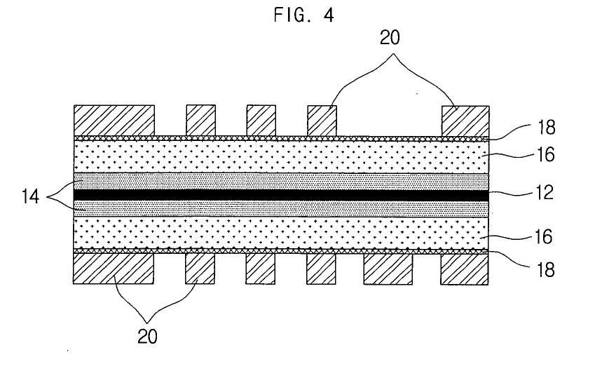

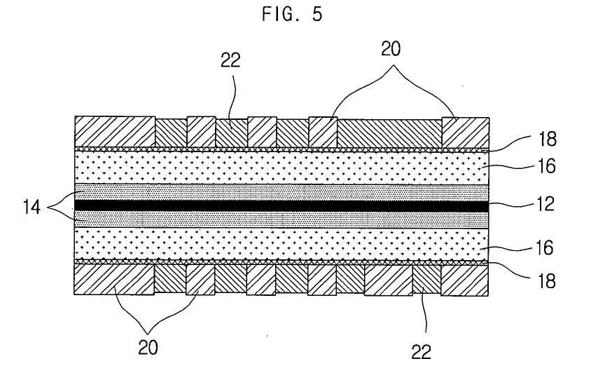

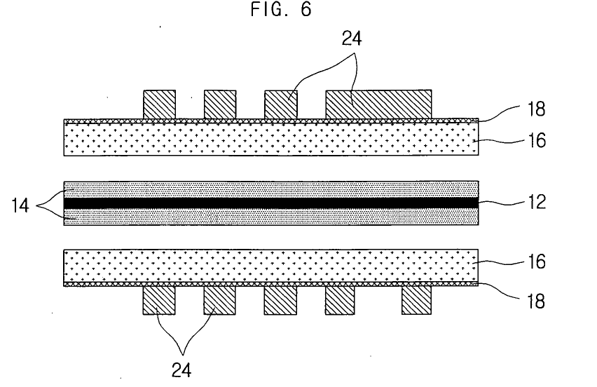

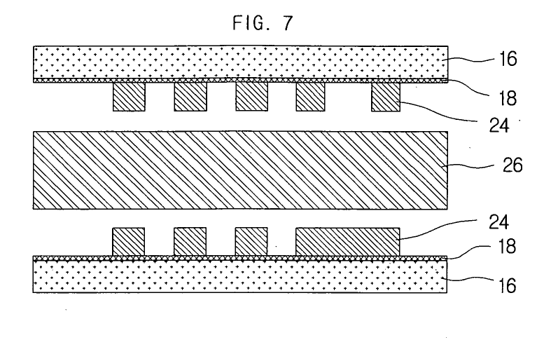

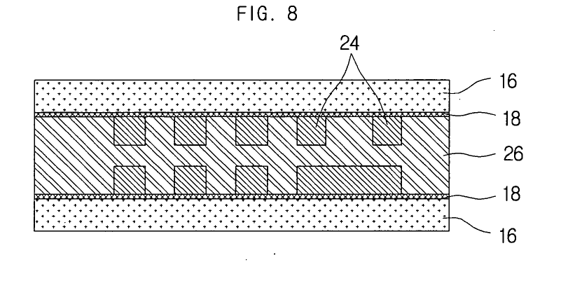

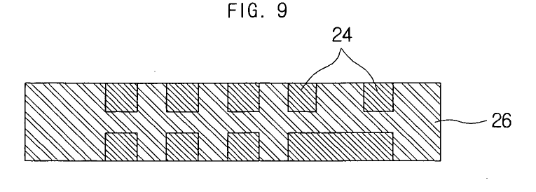

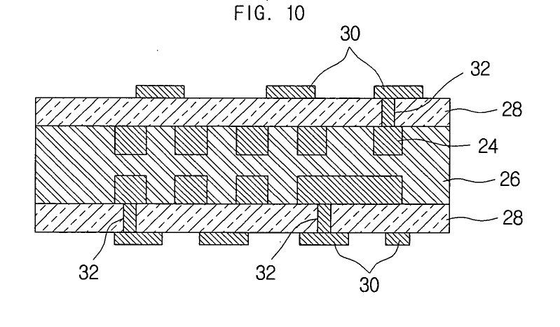

FIG. 2 is a flowchart illustrating a method for manufacturing a printed circuit board according to an embodiment of the present invention, and FIG. 3 through FIG. 10 are cross-sectional views representing a flow diagram for a method for manufacturing a printed circuit board according to an embodiment of the present invention. In FIGS. 3 to 10, there are illustrated a base layer 12, adhesive layers 14, release layers 16, metal layers 18, plating resists 20, plating 22, first circuit patterns 24, an insulation substrate 26, build-up layers 28, second circuit patterns 30, and vias 32.

A method for manufacturing a printed circuit board according to this embodiment may include forming a first circuit pattern 24 on each of a pair of release layers 16 attached to either side of a base layer 12 by adhesive layers 14, detaching the pair of release layers 16 from the base layer 12, stacking and pressing the pair of release layers 16 into an insulation substrate 26 such that the first circuit patterns 24 are buried in the insulation substrate 26, and separating the pair of release layers 16. This method makes it possible to form circuit patterns of a high density, and to shorten the process for fabricating a printed circuit board, by having a circuit pattern formed on each of the pair of release layers 16, and transferring the circuit pattern formed on each of the release layers 16 into each side of the insulation substrate 26.

In this particular embodiment, a carrier which includes the pair of release layers 16 stacked on the base layer 12 by way of the adhesive layers 14 may be used in forming the buried circuit pattern in each side of the insulation substrate 26. The circuit pattern to be buried in each side of the insulation substrate 26 may be formed over each of the pair of release layers 16, and each of the pair of release layers on which circuit patterns is formed 16 may be separated from the base layer 12, after which the pair of release layers 16 may be stacked and pressed into each side of the insulation substrate 26, so that the printed circuit board may easily be fabricated with circuit patterns formed on both sides. Since the circuit patterns can be formed on the pair of release layers 16 of the carrier in one operation, the fabrication process can be shortened.

Looking at the method for manufacturing a printed circuit board according to the present embodiment, first, a carrier may be provided which includes the pair of release layers 16 stacked over the base layer 12 by way of the adhesive layers 14, as illustrated in FIG. 3.

The carrier according to the present embodiment may include a base layer 12; a pair of adhesive layers 14, each of which is stacked on either side of the base layer 12, and which are of such quality that the adhesive strengths of the adhesive layers 14 are lowered with the application of a predetermined stimulant; and a pair of release layers 16, which are attached to the pair of adhesive layers 14 respectively.

Next, as illustrated in FIG. 4 and FIG. 5, a first circuit pattern 24 may be formed on each of the pair of release layers 16 attached on either side of the base layer 12 (S100). In order to form circuit patterns buried into each side of an insulation substrate 26, the first circuit pattern 24, which corresponds to the circuit pattern to be formed on each side of the insulation substrate 26, may be formed on each of the pair of release layers 24. Because the first circuit patterns 24 can be formed on the release layers 16 of the carrier in one process, the manufacturing process can be reduced.

In this case, as the carrier may consist of the base layer 12, the adhesive layers 14, and the release layers 16 to have a certain degree of stiffness, the handling and transportation of the carrier may be facilitated, making it possible to form precision circuit patterns, and to lower the risk of damage.

The method of forming the first circuit patterns 24 on the release layers 15 may be changed according to the quality of the release layers 16. For example, in cases where the release layers 16 are made of a conductive metal, plating resists 20 that correspond with the first circuit patterns 24 may first be formed directly over the release layers 16, and electroplating may be performed using the release layers 16 made of the conductive metal as electrodes, after which the plating resists 20 can be stripped, to form the first circuit patterns 24. Also, in cases where the release layers 15 are made of an insulating material, metal layers 18 may first be stacked over the release layers 15, and plating resists 20 that correspond with the first circuit patterns 24 may be formed over the metal layers 18, after which electroplating may be performed with the metal layers 18 as electrodes, and then, the plating resists 20, the metal layers 18, and the release layers 16 may be stripped off, so that the first patterns 24 may be formed. In cases where the release layers 16 include insulating layers and metal layers stacked over the insulating layers, it is possible to form the first circuit patterns 24 by selectively etching the metal layers.

The description for this particular embodiment will focus on the case in which the release layers 16 are made from an insulating material. That is, as illustrated in FIG. 4, a metal layer 18 may be stacked over each of the pair of release layers 16 (S101), and plating resists 20 that are in correspondence with the first circuit patterns 24 may be formed over the metal layers 18 (102). The plating resist 20 that corresponds with the circuit pattern desired in the insulation substrate 26 may be formed over each of the release layers 16. Then, as illustrated in FIG. 5, electroplating may be performed with the metal layers 18 as electrodes to fill the conductive material into those areas where the plating resists 20 are not formed (S103), after which the plating resists 20 may be stripped (S104), so that the first circuit patterns may be formed respectively on the pair of release layers 16.

Next, as illustrated in FIG. 6, the pair of release layers 16 may be detached from the base layer 12 (S200). The adhesive layer 14, of which the adhesive strength can be lowered by applying a predetermined stimulant, may be stacked over each side of the base layer 12, and the release layers 16 may be attached over the adhesive layers 16. Therefore, the release layers 16 can be detached from the adhesive layers 14 by applying the predetermined stimulant to the adhesive layers 14 in order to lower the adhesive strengths of the adhesive layers 14. In this case, the predetermined stimulant may be ultraviolet rays or heat, applied to lower the adhesive strengths of the adhesive layers 14. In the case where the adhesive layers 14 are formed using an adhesive that contains a material which generates gas when irradiated with ultraviolet rays, when detaching the release layers 16, ultraviolet rays may be irradiated. This may generate gas in the adhesive layers 14 and change the volume of adhesive layers 14, so that the adhesive strengths may be decreased.

Also, in the case where the adhesive layers 14 are formed using an expandable adhesive that contains a material in which foam is created when heated to a predetermined temperature, when detaching the release layers 16, heat may be applied to a predetermined temperature. This may foam the adhesive layers and provide an irregular adhesive surface, so that the adhesive strengths may be decreased.

Next, as illustrated in FIGS. 7 and 8, the pair of release layers 16 may be stacked and pressed into either side of the insulation substrate 26 respectively, such that the first circuit patterns 24 may be buried therein (S300). After the pair of release layers 16, on which the first circuit patterns 24 are formed, are detached from the base layer 12, the release layers 16 may respectively be stacked on either side of the insulation substrate 26 such that the first circuit patterns faced each other, and may be and pressed into the insulation substrate 26. Here, the insulation substrate 26 may contain at least one of a thermoplastic resin and a glass epoxy resin, where the insulation substrate 26 can be in a deformable state when the first circuit patterns formed on the release layers 16 are buried and transcribed into the insulation substrate 26. That is, the insulation substrate 16 can be made deformable by raising the temperature to above the transition temperature of the thermoplastic and/or glass epoxy resin, after which the release layers 16 can be stacked on and pressed into the insulation substrate 26, such that the first circuit patterns 24 formed in relievo on the release layers 16 are buried in the deformable insulation substrate 26. It is possible to use prepreg for the insulation substrate 26, in which glass fibers are impregnated with thermosetting resin to provide a semi-cured state.

Next, as illustrated in FIG. 9, the release layers 16 may be separated from the insulation substrate 26. For example, in cases where the release layers 16 are made of an insulating material, and metal layers 18 which serve as electrodes for electroplating are formed by stacking metal foils by way of an adhesive having an adhesive strength that can be lowered by applying a predetermined stimulant, the release layers 16 can be detached and removed after the predetermined stimulant is applied to lower the adhesive strengths. Also, the release layers 16 can be detached and removed by physical abrasion.

When the release layers 16 are separated, the metal layers 18 serving as electrodes for electroplating may be removed. That is, in the case where the release layers 16 are made of insulating materials as presented in this embodiment, the metal layers 18 may remain even after the release layers 16 are removed, and thus the metal layers 18 may be removed by etching, etc.

Next, as illustrated in FIG. 10, build-up layers 28 may be stacked over the insulation substrate 26 (S500), and vias 32 electrically connected with the first circuit patterns 24, as well as second circuit patterns 30, may be formed in the build-up layers 28 (S600). The build-up layers 28 may be made of an insulating material, and multiple insulating layers may be stacked over the insulation substrate 26 by a build-up method, to fabricate a multilayer printed circuit board. That is, insulating material may be stacked over the insulation substrate 26 into which the first circuit patterns 23 are buried, and vias 32 electrically connected with the first circuit patterns 24 and second circuit patterns may be formed to complete the build-up layers 28. Multiple build-up layers 28 can be implemented by repeating the above process. As such, multiple build-up layers 28 may be stacked, and the vias 32 and the second circuit patterns 30 may be formed in each of the multiple build-up layers, to fabricate a multilayer printed circuit board.

This particular embodiment presents a configuration in which one build-up layer is stacked over either side of the insulation substrate 26, as illustrated in FIG. 10.

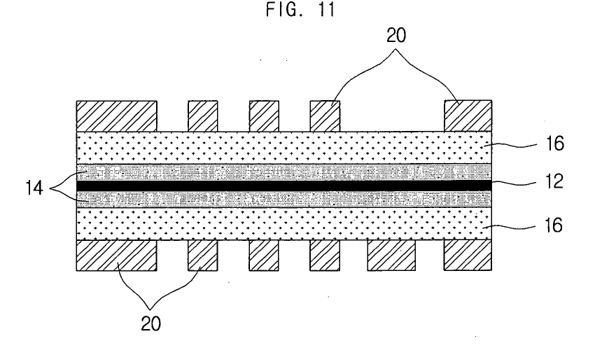

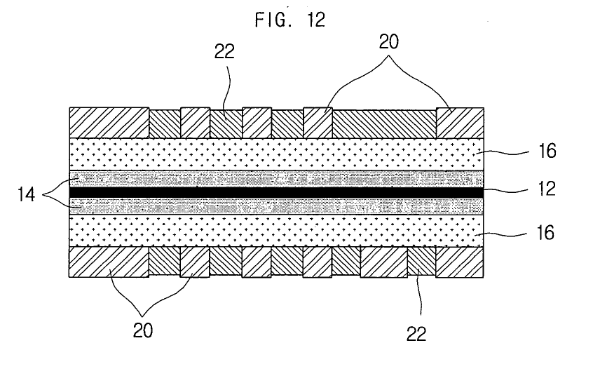

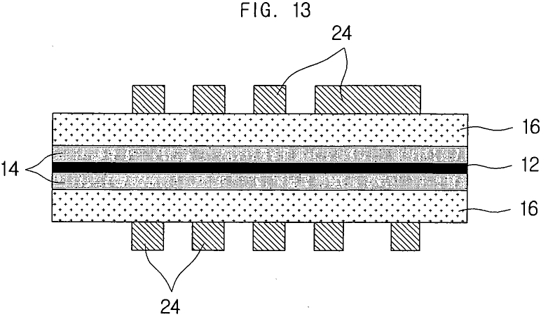

FIG. 11 through FIG. 13 are cross-sectional views representing a flow diagram for a portion of a method for manufacturing a printed circuit board according to another embodiment of the present invention. In FIGS. 11 through 13, there are illustrated a base layer 12, adhesive layers 14, release layers 16, plating resists 20, plating 22, and first circuit patterns 24.

In describing this particular embodiment, a method of forming circuit patterns is presented where the release layers 16 are made of a conductive metal.

When the release layers 6 are made of a conductive metal, as illustrated in FIG. 11, the plating resists 20 corresponding to the first circuit patterns 24 may be formed respectively over the pair of release layers 16. Electroplating may be performed, with the release layers 16 made of the conductive metal acting as electrodes, to fill the conductive material into those areas over which the plating resists 20 are not formed, and then the plating resists 20 may be removed, to form the first circuit patterns 24 on the release layers 16.

Afterwards, the release layers 16 may be detached, and then may be stacked and pressed onto the insulation substrate such that the first circuit patterns 24 formed on the release layers 16 are buried into the insulation substrate.

Other elements of this embodiment are substantially the same as those of the previously described embodiment, and thus will not be described again.

According to certain aspects of the invention as set forth above, by forming a circuit pattern on each of a pair of release layers with a single process, and transferring the circuit pattern into each side of an insulation substrate, the manufacturing process can be shortened and circuit patterns can be formed to a high density.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A carrier comprising:
a base layer;
a pair of adhesive layers each stacked over either side of the base layer, the adhesive layers being of such quality that the adhesive strengths of the adhesive layers are lowered with an application of a predetermined stimulant; and
a pair of release layers attached respectively to the pair of adhesive layers.

2. The carrier of claim 1, wherein the release layers comprise at least one of a conductive metal and an insulating material.

3. The carrier of claim 2, wherein the conductive metal includes at least one or more selected from a group consisting of copper (Cu), gold (Au), silver (Ag), nickel (Ni), palladium (Pd), and platinum (Pt).

4. The carrier of claim 2, wherein the insulating material includes at least one or more selected from a group consisting of epoxy resin, polyimide, phenol, fluorine resin, PPO (polyphenylene oxide) resin, BT (bismaleimide triazine) resin, glass fiber, and paper.

5. The carrier of claim 1, wherein the predetermined stimulant is ultraviolet rays or heat.

6. The carrier of claim 1, wherein the adhesive layers are made from expandable adhesive

7. A method for manufacturing a printed circuit board, the method comprising;
forming a first circuit pattern on each of a pair of release layers, the release layers attached respectively to either side of a base layer by way of adhesive layers;
detaching the pair of release layers from the base layer;
stacking and pressing the pair of release layers respectively onto either side of an insulation substrate such that the first circuit patterns are buried in the insulation substrate; and
separating the pair of release layers.

8. The method of claim 7, further comprising, after the separating of the pair of release layers:
stacking a build-up layer over the insulation substrate and forming a via and a second circuit pattern, the via electrically connected with the first circuit pattern.

9. The method of claim 8, wherein a plurality of build-up layers are stacked, and the via and the second circuit pattern are formed on each build-up layer.

10. The method of claim 7, wherein the release layers are made of a conductive metal, and the forming of the first circuit pattern comprises:
forming a plating resist over the release layer, the plating resist being in correspondence with the first circuit pattern;
performing electroplating with the conductive metal as an electrode; and
removing the plating resist,
and wherein the separating of the pair of release layers comprises:
etching the conductive metal.

11. The method of claim 7, wherein the release layers are made of an insulating material, and the forming of the first circuit pattern comprises:
forming a metal layer over the release layer;
forming a plating resist in correspondence with the first circuit pattern;
performing electroplating with the metal layer as an electrode; and
removing the plating resist.

12. The method of claim 7, wherein the release layer comprises an insulation layer and a metal layer stacked on the insulation layer, and the forming of the first circuit pattern comprises:
forming an etching resist over the release layer, the etching resist being in correspondence with the first circuit pattern;
etching the metal layer; and
removing the etching resist.

13. The method of claim 7, wherein the adhesive layers are of such quality that the adhesive strengths of the adhesive layers are lowered with an application of a predetermined stimulant, and the detaching of the pair of release layers comprises:
applying the predetermined stimulant to the adhesive layers.

14. The method of claim 13, wherein the predetermined stimulant is ultraviolet rays or heat.

15. The method of claim 7, wherein the adhesive layers are made from expandable adhesive.
